(19) United States
(12) Patent Application Publication
(10) Pub. No.: US 2012/0032673 A1
(43) Pub. Date: Feb. 9, 2012

(54) MAGNETIC SENSOR

(75) Inventors: Shuji MAEKAWA, Miyagi-ken (JP); Kota ASATSUMA, Miyagi-ken (JP); Fumihito KOIKE, Miyagi-ken (JP); Hideto ANDO, Miyagi-ken (JP)

(73) Assignee: ALPS ELECTRIC CO., LTD., Tokyo (JP)

(21) Appl. No.: 13/274,258

(22) Filed: Oct. 14, 2011

Related U.S. Application Data
(63) Continuation of application No. PCT/JP2010/058874, filed on May 26, 2010.

(30) Foreign Application Priority Data
May 29, 2009 (JP) 2009-129898

(51) Int. Cl. G01R 33/02

(52) U.S. Cl. 324/252

(57) ABSTRACT

First magnetoresistive effect elements and second magnetoresistive effect elements and are formed on the same substrate. A pinned magnetic layer of each of the first magnetoresistive effect elements has a three-layer laminated ferrimagnetic structure including magnetic layers. A pinned magnetic layer of each of the second magnetoresistive effect elements has a two-layer laminated ferrimagnetic structure including magnetic layers. The magnetization direction of the third magnetic layer of each of the magnetoresistive effect elements is antiparallel to the magnetization direction of the second magnetic layer of each of the second magnetoresistive effect elements.

### CLAIM OF PRIORITY

This application is a Continuation of International Application No. PCT/JP2010/058874 filed on May 26, 2010, which claims benefit of Japanese Patent Application No. 2009-129898 filed on May 29, 2009. The entire contents of each application noted above are hereby incorporated by reference.

### BACKGROUND OF THE INVENTION

1. Field of the Invention

The present invention relates to a magnetic sensor including a plurality of magnetoresistive effect elements provided on the same substrate, the magnetoresistive effect elements each including a pinned magnetic layer formed into a laminated ferrimagnetic structure including a plurality of magnetic layers and nonmagnetic intermediate layers provided between the respective magnetic layers.

2. Description of the Related Art

A magnetic sensor provided with a bridge circuit (detection circuit) formed by using a plurality of magnetoresistive effect elements uses magnetoresistive effect elements of two types which have electric characteristics reverse to each other with respect to an external magnetic field in order to increase output. When GMR elements (giant magnetoresistive effect elements) are used as magnetoresistive effect elements, the magnetization direction of a pinned magnetic layer constituting each of the GMR elements used as one of the types of magnetoresistive effect elements is reversed to that in the other type of magnetoresistive effect elements, thereby exhibiting opposite electric characteristics.

These GMR elements are first formed on the same substrate and heat-treated in a magnetic field to adjust the magnetization directions of the pinned magnetic layers of all GMR elements in the same direction. Then, the substrate is divided into a plurality of GMR element groups to form chips, and the chips are mounted on a common support substrate under a condition where one of the chips is rotated 180 degrees with respect to the other chip so that the magnetization direction of the pinned magnetic layers of the GMR elements arranged in one of the chips is antiparallel to the magnetization direction of the pinned magnetic layers of the GMR elements arranged on the other chip. Further, an electrode portion of the support substrate is wire-bonded to a pad of each of the chips.

However, in the magnetic sensor manufactured as described above, it is necessary to arrange in parallel, on the support substrate, the chips which are different from each other in the magnetization direction of the pinned magnetic layer in each of the GMR elements. Further, a wire bonding area where the support substrate is wire-bonded to each of the chips is required, thereby causing the problem of increasing the size of the magnetic sensor.

In general, a series of working steps of cutting a substrate into plural chips, rotating one of the chips by 180 degrees, and bonding (die bonding) each of the chips to a support substrate is required. In addition, the number of products which may be produced per substrate is decreased, thereby causing the problem of complicating the manufacturing process and increasing the manufacturing cost. Further, variation easily occurs during manufacture, thereby causing variation in detection accuracy of magnetic sensors.

The inventions described in International Publication No. 94/15223 and Japanese Unexamined Patent Application Publication No. 2002-140805 do not relate to a magnetic sensor including a plurality of magnetoresistive effect elements which are different from each other in magnetization direction of a pinned magnetic layer and which constitute a detection circuit for an external magnetic field, and means for resolving the above-described problems of related art is not described.

### SUMMARY OF THE INVENTION

Accordingly, the present invention provides a magnetic sensor with high detection accuracy at low cost, wherein the magnetization directions of pinned magnetic layers of a plurality of magnetoresistive effect elements may be adjusted to be antiparallel to each other using one chip.

According to the present invention, a magnetic sensor includes a plurality of magnetoresistive effect elements which constitute a detection circuit for an external magnetic field. The magnetoresistive effect elements each have a laminated structure including a pinned magnetic layer having a pinned magnetization direction, a free magnetic layer which has a magnetization direction varying with the external magnetic field and which is laminated on the pinned magnetic layer with a nonmagnetic layer provided therebetween, and an antiferromagnetic layer which is formed on the pinned magnetic layer on the side opposite to the nonmagnetic layer and which produces an exchange coupling magnetic field with the pinned magnetic layer by heat treatment in a magnetic field. The pinned magnetic layer has a laminated ferrimagnetic structure including a plurality of magnetic layers and a nonmagnetic intermediate layer interposed between the respective magnetic layers. Of the plurality of magnetoresistive effect elements, a first magnetoresistive effect element including an odd number of magnetic layers and a second magnetoresistive effect element including an even number of magnetic layers are deposited on the same substrate. The magnetization direction of the magnetic layer in contact with the nonmagnetic layer among the magnetic layers constituting the pinned magnetic layer of the first magnetoresistive effect element is antiparallel to the magnetization direction of the magnetic layer in contact with the nonmagnetic layer among the magnetic layers constituting the pinned magnetic layer of the second magnetoresistive effect element.

According to the present invention, the magnetic sensor may be formed using one chip, and thus it is possible to accelerate miniaturization of the magnetic sensor, decrease manufacturing variation, and further increase the number of the products produced. Thus, the manufacturing cost may be suppressed, and high detection accuracy may be achieved.

In the present invention, the first magnetoresistive effect element and the second magnetoresistive effect element preferably have a substantially equal rate of resistance change (ΔMR) and temperature characteristic (TCΔMR). In the present invention, the rate of resistance change (ΔMR) and temperature characteristic (TCΔMR) of the first magnetoresistive effect element may be simply and appropriately adjusted to those of the second magnetoresistive effect element by, for example, adjusting the thickness of the magnetic layer in contact with the nonmagnetic layer and the thickness of the magnetic layer in contact with the antiferromagnetic layer among the magnetic layers constituting the first magnetoresistive effect element.

Also, in the present invention, preferably, the number of the magnetic layers in the first magnetoresistive effect element is 3, and the number of the magnetic layers in the second magnetoresistive effect element is 2. Therefore, the rate of resistance change (ΔMR) and temperature characteristic (TCΔMR) of the first magnetoresistive effect element may be simply and appropriately adjusted to those of the second magnetoresistive effect element, and both the first magnetoresistive effect element and the second magnetoresistive effect element may be adjusted to have high heat resistant reliability against a disturbance magnetic field and a high rate of resistance change (ΔMR).

In addition, in the present invention, the pinned magnetic layer constituting the first magnetoresistive effect element includes a first magnetic layer, the nonmagnetic intermediate layer, a second magnetic layer, the nonmagnetic intermediate layer, and a third magnetic layer, which are laminated in order from the side in contact with the antiferromagnetic layer, the third magnetic layer being in contact with the nonmagnetic layer.

The thickness of the second magnetic layer is preferably larger than the thicknesses of the first magnetic layer and the third magnetic layer. Thus, the heat resistance reliability of the first magnetoresistive effect element against a disturbance magnetic field may be improved, and a decrease in rate of resistance change (ΔMR) may be appropriately suppressed.

In addition, the present invention, the relationship, the thickness of the second magnetic layer>the thickness of the third magnetic layer>the thickness of the first magnetic layer, is preferably satisfied. An increase in thickness of the third magnetic layer may increase the rate of resistance change (ΔMR), while a decrease in thickness of the first magnetic layer may increase the exchange coupling magnetic field (Hex) with the antiferromagnetic layer and may enhance the magnetization pinning force of the pinned magnetic layer.

In addition, in the present invention, the relationship, 0.5 Å<(the thickness of the first magnetic layer+the thickness of the third magnetic layer−the thickness of the second magnetic layer)<1.5 Å, is preferably satisfied. In this case, the heat resistance reliability of the first magnetoresistive effect element against the disturbance magnetic field may be improved, and a high rate of resistance change (ΔMR) may be achieved.

In addition, in the present invention, (the thickness of the first magnetic layer+the thickness of the third magnetic layer−the thickness of the second magnetic layer) may be adjusted in a range of −2.5 Å to −1.5 Å.

In addition, in the present invention, in addition to the limit of the thickness of each of the magnetic layers, preferably, the first magnetic layer is composed of CoxFe100-x (x is in a range of 60 to 100 at %), and the second magnetic layer and the third magnetic layer are composed of CoyFe100-y (y is in a range of 80 to 100 at %).

In addition, in the present invention, when the saturation magnetization of each of the magnetic layers is Ms, and the thickness of each of the magnetic layers is t, Ms·t of the second magnetic layer is preferably substantially equal to the total of Ms·t of the first magnetic layer and Ms·t of the third magnetic layer. In this case, the heat resistance reliability of the first magnetoresistive effect element against the disturbance magnetic field may be more effectively improved, and a high rate of resistance change (ΔMR) may be more effectively achieved.

In addition, in the present invention, preferably, the plan-view pattern dimensions of the first magnetoresistive effect element are different from those of the second magnetoresistive effect element, and the value of element resistance of the first magnetoresistive effect element is substantially the same as that of the second magnetoresistive effect element.

In addition, in the present invention, preferably, the first magnetoresistive effect element and the second magnetoresistive effect element are laminated with an insulating layer provided therebetween. In this case, miniaturization of the magnetic sensor may be more effectively promoted.

According to the present invention, a magnetic sensor may be formed with one chip, and thus it is possible to promote miniaturization of the magnetic sensor, decrease manufacturing variation, and further increase the number of the products produced. Thus, the manufacturing cost may be suppressed, and high detection accuracy may be achieved.

### BRIEF DESCRIPTION OF THE DRAWINGS

FIG. 1 is a perspective view of a magnetic sensor according to an embodiment of the present invention;

FIG. 2 is an enlarged partial longitudinal sectional view of a magnetic sensor according to an embodiment of the present invention;

FIGS. 3A and 3B are enlarged longitudinal sectional views of laminated structures of a first magnetoresistive effect element and a second magnetoresistive effect element, respectively;

FIG. 4 is a circuit diagram of a magnetic sensor according to an embodiment of the present invention;

FIG. 5 is a graph showing R-H characteristics of a first magnetoresistive effect element;

FIG. 6 is a graph showing R-H characteristics of a second magnetoresistive effect element;

FIG. 7 is a graph showing a relationship between the rate of resistance change (ΔMR) and the thickness of a second magnetic layer or a third magnetic layer which constitutes a pinned magnetic layer of a first magnetoresistive effect element;

FIG. 8 is a graph showing a relationship between the temperature characteristic (TCΔMR) and the thickness of a first magnetic layer which constitutes a pinned magnetic layer of a first magnetoresistive effect element;

FIG. 9 is a graph showing a relationship between normalized Hpl and (thickness of first magnetic layer+thickness of third magnetic layer−thickness of second magnetic layer) of a first magnetoresistive effect element; and

FIG. 10 is a graph showing a relationship between the rate of resistance change (ΔMR) and (thickness of first magnetic layer+thickness of third magnetic layer−thickness of second magnetic layer) of a first magnetoresistive effect element.

### DESCRIPTION OF THE PREFERRED EMBODIMENTS

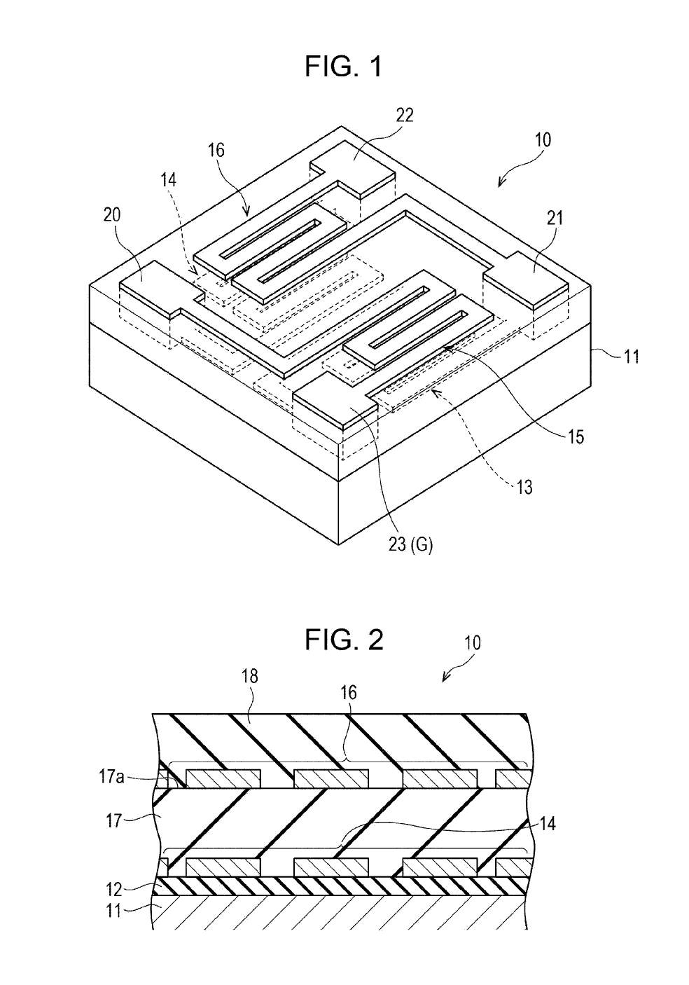

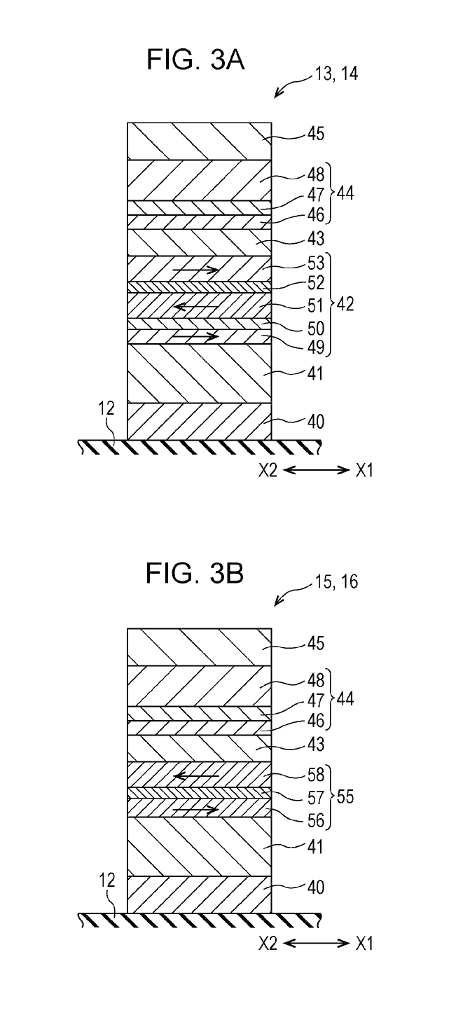

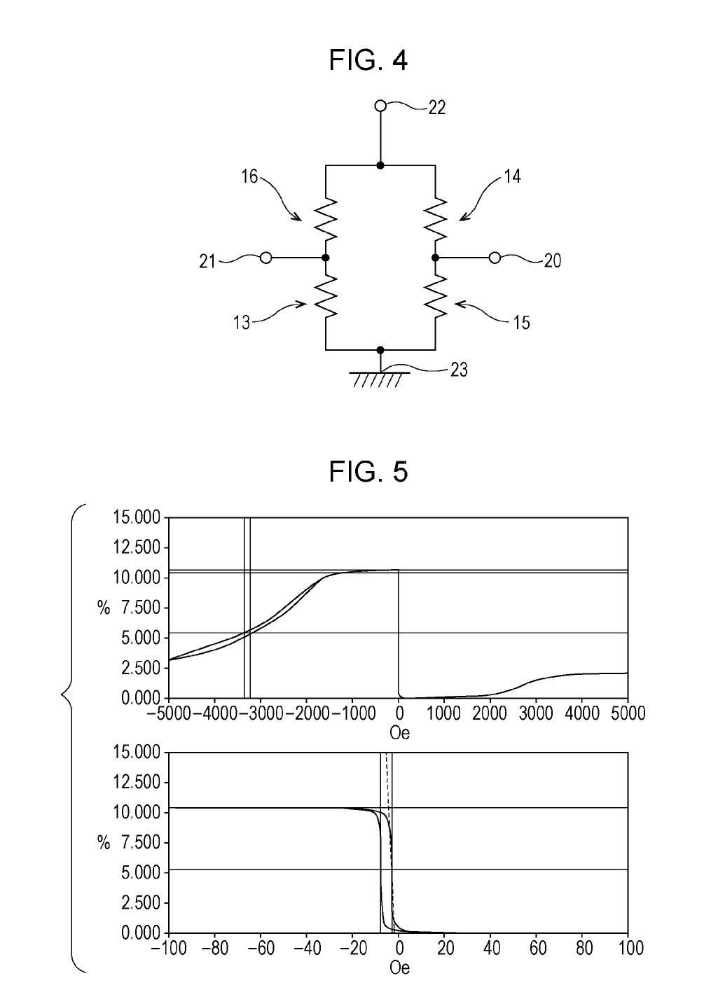

FIG. 1 is a perspective view of a magnetic sensor according to an embodiment of the present invention, FIG. 2 is a enlarged partial longitudinal sectional view of the magnetic sensor shown in FIG. 1, FIGS. 3A and 3B are enlarged longitudinal sectional views showing laminated structures of a first magnetoresistive effect element and a second magnetoresistive effect element, respectively, and FIG. 4 is a circuit diagram of a magnetic sensor according to an embodiment of the present invention.

As shown in FIGS. 1 and 2, a magnetic sensor 10 according to an embodiment of the present invention includes two first magnetoresistive effect elements 13 and 14 and two second magnetoresistive effect elements 15 and 16, the first magnetoresistive effect elements and the second magnetoresistive effect elements being laminated on the same substrate 11 with an insulating intermediate layer provided therebetween.

As shown in FIG. 2, an insulating under layer 12 is formed on the substrate 11, and the first magnetoresistive effect elements 13 and 14 are formed on the insulating under layer 12. In addition, the second magnetoresistive effect elements 15 and 16 are formed on the planarized surface 17a of the insulating intermediate layer 17. As shown in FIG. 2, the second magnetoresistive effect elements 15 and 16 are covered with a protective layer 18. In this case, the insulating under layer 12 is composed of Al2O3 with a thickness of, for example, about 1000 Å. The insulating intermediate layer 17 is formed into a laminated structure including from below, for example, an Al2O3 layer with a thickness of about 1000 Å, a SiO2 layer or SiN layer with a thickness of about 5000 Å to 20,000 Å, and an Al2O3 layer with a thickness of about 1000 Å.

The insulating intermediate layer 17 preferably has a three-layer structure as described above. A first insulating layer, a second insulating layer, and a third insulating layer are laminated in order from below, and an Al2O3 layer constituting the first insulating layer protects the first magnetoresistive effect elements 13 and 14 from oxidation or the like. A SiO2 layer or SiN layer constituting the second insulating layer electrically isolates the first magnetoresistive effect elements 13 and 14 from the second magnetoresistive effect elements 15 and 16 and has a thickness necessary and sufficient for ESD resistance. In addition, an Al2O3 layer constituting the third insulating layer is provided for achieving stability of the GMR characteristics of the second magnetoresistive effect elements 15 and 16. In particular, in order to secure ESD resistance, it is necessary that the thickness of the second insulating layer is 5000 Å or more, and more preferably 10,000 Å or more. Also, an excessive increase in thickness of the second insulating layer increases the deposition process time and the etching process time required for forming a through hole for vertical contact of an electrode. Therefore, the thickness of the second insulating layer is preferably 20,000 Å or less and particularly preferably 15,000 Å or less.

The protective layer 18 includes an Al2O3 layer or SiO2 layer of about 2000 Å. In addition, the above-described insulation configuration is only an example. The inorganic insulating materials are used in the above-described configuration, but organic insulating materials may be used.

As shown in FIG. 1, the first magnetoresistive effect elements 13 and 14 and the second magnetoresistive effect elements 15 and 16 are formed in a meander shape. In addition, as shown in FIG. 2, the first magnetoresistive effect elements 13 and 14 and the second magnetoresistive effect elements 15 and 16 are formed so as to overlap with the insulating intermediate layer 17 provided therebetween.

As shown in FIG. 1, two output electrodes 20 and 21, an input electrode 22, and a ground electrode 23 are formed to pass through the insulating intermediate layer 17. The end of one of the first magnetoresistive effect elements and the end of one of the second magnetoresistive effect elements are electrically connected to each of the electrodes, forming a bridge circuit (detection circuit) shown in FIG. 4.

The method for manufacturing the magnetic sensor 10 shown in FIGS. 1 and 2 is described. For example, first, a laminated film for forming the first magnetoresistive effect elements is formed over the entire in-plane region of the substrate 11 by a sputtering method or the like, and the meander-shaped first magnetoresistive effect elements 13 and 14 are formed using an etching method. In addition, the ends of the first magnetoresistive effect elements 13 and 14 are extended to each of electrode-forming regions.

Then, the insulating intermediate layer 17 is formed on the first magnetoresistive effect elements 13 and 14, and the second magnetoresistive effect elements 15 and 16 are formed on the insulating intermediate layer 17. For example, a laminated film for forming the second magnetoresistive effect elements is formed over the entire in-plane region of the substrate 11 by a sputtering method or the like, and the meander-shaped second magnetoresistive effect elements 15 and 15 are formed using an etching method. In addition, the ends of the second magnetoresistive effect elements 15 and 16 are extended to each of electrode-forming regions.

Then, a through hole is formed in the insulating layer 17 within the formation region of each of the electrodes 20 to 23, and the through hole is filled, by plating or the like, with a conductive layer serving as each of the electrodes 20 to 23. As a result, the end of each of the magnetoresistive effect elements 13 to 16 is electrically connected to each of the electrodes 20 to 23.

FIG. 3A is a longitudinal sectional view showing a laminated structure of each of the first magnetoresistive effect elements 13 and 14, and FIG. 3B a longitudinal sectional view showing a laminated structure of each of the second magnetoresistive effect elements 15 and 16.

As shown in FIG. 3A, each of the first magnetoresistive effect elements 13 and 14 is a giant magnetoresistive effect element (GMR element) including a seed layer 40, an antiferromagnetic layer 41, a pinned magnetic layer 42, a nonmagnetic layer 43, a free magnetic layer 44, and a protective layer 45, which are laminated in order from below.

The seed layer 40 is composed of, for example, Ni—Fe—Cr. The antiferromagnetic layer 41 is composed of an antiferromagnetic material such as an Ir—Mn alloy (iridium-manganese alloy) or a Pt—Mn alloy (platinum-manganese alloy). The nonmagnetic layer 43 is composed of Cu (copper) or the like. The free magnetic layer 44 is composed of a soft magnetic material such as a Ni—Fe alloy (nickel-iron alloy). In this embodiment, the free magnetic layer 44 has a three-layer laminated structure in which a first Co—Fe layer 46, a second Co—Fe layer 47, and a Ni—Fe layer 48 are laminated in order from below. The Co concentration of the first Co—Fe layer 46 is preferably higher than the Co concentration of the second Co—Fe layer 47. For example, the first Co—Fe layer 46 is composed of CozFe100-z (z is in a range of 80 to 100 at %), and the second Co—Fe layer 47 is composed of CowFe100-w (w is in a range of 60 to 100 at %). In addition, the free magnetic layer 44 may have a two-layer structure or a single-layer structure. The protective layer 45 is composed of Ta (tantalum) or the like.

As shown in FIG. 3A, the pinned magnetic layer 42 of each of the first magnetoresistive effect elements 13 and 14 has a laminated ferrimagnetic structure in which a first magnetic layer 49, a nonmagnetic intermediate layer 50, a second magnetic layer 51, a nonmagnetic intermediate layer 52, and a third magnetic layer 53 are laminated in order from below. For example, the first magnetic layer 49, the second magnetic layer 51, and the third magnetic layer 53 are all composed of a Co—Fe alloy, and the nonmagnetic intermediate layers 50 and 52 are composed of Ru (ruthenium) or the like.

An exchange coupling magnetic field (Hex) is produced between the antiferromagnetic layer 41 and the first magnetic layer 49 by heat treatment in a magnetic field, and RKKY interaction is produced between the first magnetic layer 49 and the second magnetic layer 51 and between the second magnetic layer 51 and the third magnetic layer 53, so that the magnetization directions of the magnetic layers 49 and 51 facing each other with the nonmagnetic intermediate layer 50 therebetween are pinned in an antiparallel state, and the magnetization directions of the magnetic layers 51 and 53 facing each other with the nonmagnetic intermediate layer 52 therebetween are pinned in an antiparallel state. As shown in FIG. 3A, for example, the magnetization directions of the first magnetic layer 49 and the third magnetic layer 53 are direction X1, and the magnetization direction of the second magnetic layer 51 is direction X2.

As shown in FIG. 3B, each of the second magnetoresistive effect elements 15 and 16 is a giant magnetoresistive effect element (GMR element) including a seed layer 40, an antiferromagnetic layer 41, a pinned magnetic layer 55, a nonmagnetic layer 43, a free magnetic layer 44, and a protective layer 45, which are laminated in order from below. As shown in FIG. 3B, the pinned magnetic layer 55 constituting each of the second magnetoresistive effect elements 15 and 16 has a laminated ferrimagnetic structure in which a first magnetic layer 56, a nonmagnetic intermediate layer 57, and a second magnetic layer 58 are laminated in order from below. For example, the first magnetic layer 56 and the second magnetic layer 58 are both composed of a Co—Fe alloy, and the nonmagnetic intermediate layer 57 is composed of Ru (ruthenium) or the like.

An exchange coupling magnetic field (Hex) is produced between the antiferromagnetic layer 41 and the first magnetic layer 56 by heat treatment in a magnetic field, and RKKY interaction is produced between the first magnetic layer 56 and the second magnetic layer 58, so that the magnetization directions of the first magnetic layers 56 and 58 are pinned in an antiparallel state. As shown in FIG. 3B, for example, the magnetization direction of the first magnetic layer 56 is direction X1, and the magnetization direction of the second magnetic layer 58 is direction X2.

In the embodiment, as shown in FIGS. 3A and 3B, the magnetization direction (direction X1) of the third magnetic layer 53 in contact with the nonmagnetic layer 43 among the magnetic layers constituting the pinned magnetic layer 42 of each of the first magnetoresistive effect elements 13 and 14 is antiparallel to the magnetization direction (direction X2) of the second magnetic layer 58 in contact with the nonmagnetic layer 43 among the magnetic layers constituting the pinned magnetic layer 55 of each of the second magnetoresistive effect elements 15 and 16.

On the other hand, the magnetization direction of the free magnetic layer 44 changes with an external magnetic field. For example, when an external magnetic field acts in the direction X1, the magnetization of the free magnetic layer 44 is oriented in the direction X1. In this case, in each of the first magnetoresistive effect elements 13 and 14, the magnetization direction (direction X1) of the third magnetic layer 53 in contact with the nonmagnetic layer 43 is parallel with the magnetization direction of the free magnetic layer 44, thereby minimizing (Rmin) the value of electric resistance of each of the first magnetoresistive effect elements 13 and 14. On the other hand, in each of the second magnetoresistive effect elements 15 and 16, the magnetization direction (direction X2) of the second magnetic layer 58 in contact with the nonmagnetic layer 43 is antiparallel to the magnetization direction of the free magnetic layer 44, thereby maximizing (Rmax) the value of electric resistance of each of the second magnetoresistive effect elements 15 and 16. Therefore, the electric characteristics of the first magnetoresistive effect elements 13 and 14 are reverse to the electric characteristics of the second magnetoresistive effect elements 15 and 16.

Examples of R-H characteristics of the first magnetoresistive effect elements 13 and 14 and the second magnetoresistive effect elements 15 and 16 are described below. The film structure of each of the magnetoresistive effect elements used in experiments is as follows.

The first magnetoresistive effect elements 13 and 14 each had a film configuration including, in order from below, a substrate/a seed layer 40: NiFeCr/an antiferromagnetic layer: IrMn/a pinned magnetic layer 42: [a first magnetic layer 49: Co70 at % Fe30 at % (X)/a nonmagnetic intermediate layer 50: Ru/a second magnetic layer 51: Co90 at % Fe10 at % (Y)/a nonmagnetic intermediate layer 52: Ru/a third magnetic layer: Co90 at % Fe10 at % (Z)]/a nonmagnetic layer 43: Cu/a free magnetic layer 44: [CoFe/NiFe]/a protective layer: Ta.

The second magnetoresistive effect elements 15 and 16 each had a film configuration including, in order from below, a substrate/a seed layer 40: NiFeCr/an antiferromagnetic layer: IrMn/a pinned magnetic layer 55: [a first magnetic layer 56: CoFe/a nonmagnetic intermediate layer 57: Ru/a second magnetic layer 58: CoFe]/a nonmagnetic layer 43: Cu/a free magnetic layer 44: [CoFe/NiFe]/a protective layer: Ta.

In the above-described film configurations, parenthesized X, Y, and Z each denote a thickness.

After each of the magnetoresistive effect elements was formed, heat treatment was performed in a magnetic field.

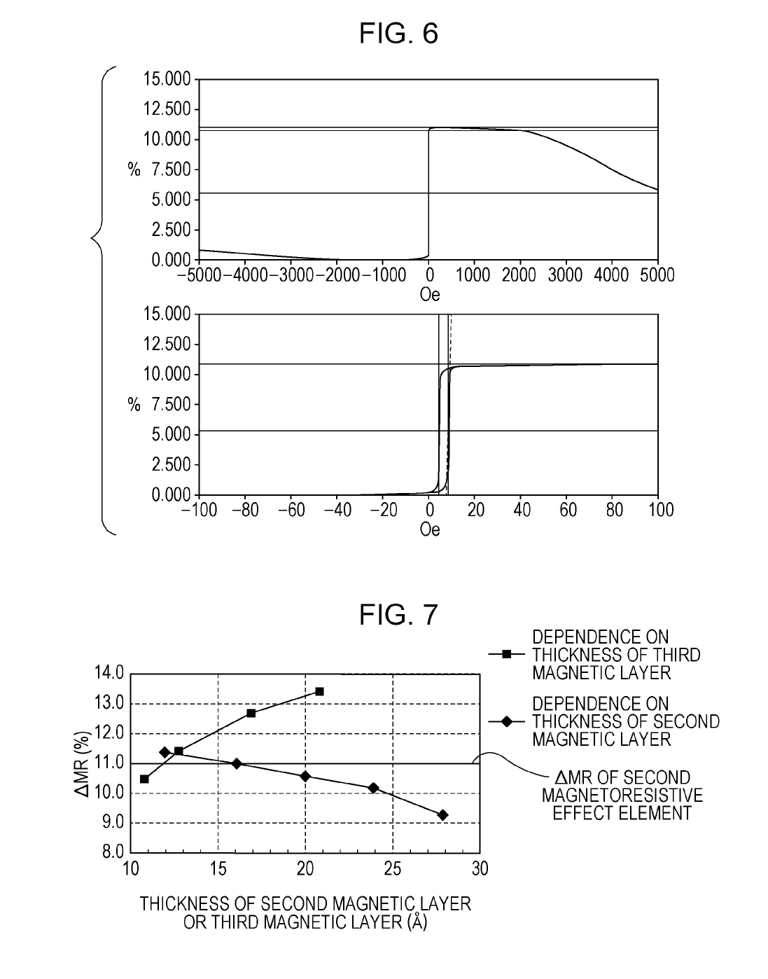

FIG. 5 shows the R-H characteristics of the first magnetoresistive effect elements 13 and 14, and FIG. 6 shows the R-H characteristics of the second magnetoresistive effect elements 15 and 16. In each of FIGS. 5 and 6, a major loop is shown in an upper portion, and a minor loop is shown in a lower portion.

Also, in a graph of each of FIGS. 5 and 6, the magnitude of an external magnetic field is shown on the abscissa, and the rate of resistance change (ΔMR) is shown on the ordinate.

FIGS. 5 and 6 indicate that with respect to the external magnetic field, the electric characteristics of the first magnetoresistive effect elements 13 and 14 are reverse to those of the second magnetoresistive effect elements 15 and 16. In these graphs, 1 Oe is about 80 A/m.

In addition, a bridge circuit shown in FIG. 4 is formed using the first magnetoresistive effect elements 13 and 14 and the second magnetoresistive effect elements 15 and 16 according to the embodiment. In the bridge circuit shown in FIG. 4, the outputs from the output electrodes 20 and 21 vary on the basis of variation in the values of electric resistance of the first magnetoresistive effect elements 13 and 14 and the second magnetoresistive effect elements 15 and 16. The output electrodes 20 and 21 are connected to a differential amplifier of an integrated circuit not shown so that a differential output may be obtained.

As shown in FIGS. 1 and 2, in the embodiment, the first magnetoresistive effect elements 13 and 14 and the second magnetoresistive effect elements 15 and 16 are laminated with the insulating intermediate layer 17 therebetween on the same substrate 11, and thus the magnetic sensor 10 may be formed from one chip without the need for a wire bonding area unlike in a conventional sensor. Therefore, miniaturization of the magnetic sensor 10 may be promoted. In addition, in comparison with a case where the magnetic sensor 10 is formed using a plurality of chips as in a conventional one, positioning between the chips is not required, thereby decreasing manufacturing variation and further increasing the number of the products produced. Thus, the manufacturing cost may be suppressed, and detection accuracy may be improved.

Further, in the embodiment, the number of the magnetic layers 49, 51, and 53 constituting the fixed magnetic layer 42 of each of the first magnetoresistive effect elements 13 and 14 is an odd number, and the number of the magnetic layers 56 and 58 constituting the fixed magnetic layer 55 of each of the second magnetoresistive effect elements 15 and 16 is an even number. In this case, even in a one-chip configuration, the magnetization direction of the magnetic layer (third magnetic layer) 53 in contact with the nonmagnetic layer 43 of each of the first magnetoresistive effect elements 13 and 14 may be made antiparallel to the magnetization direction of the magnetic layer (second magnetic layer) 58 in contact with the nonmagnetic layer 43 of each of the second magnetoresistive effect elements 15 and 16 by one time of heat treatment in a magnetic field.

As described above, the heat treatment in a magnetic field is performed for producing an exchange coupling magnetic field (Hex) between the antiferromagnetic layer 41 and each of the first magnetic layers 49 and 56. After both the first magnetoresistive effect elements 13 and 14 and the second magnetoresistive effect elements 15 and 16 are formed, the heat treatment in a magnetic field may be simultaneously performed for the first magnetoresistive effect elements 13 and 14 and the second magnetoresistive effect elements 15 and 16.

In the embodiment, the rate of resistance change (ΔMR) and temperature characteristics (TCΔMR and TCR) of the first magnetoresistive effect elements 13 and 14 are made substantially equal to those of the second magnetoresistive effect elements 15 and 16, so that high detection accuracy may be stably obtained. The expression “substantially equal” represents the concept that an error of about ±10% in terms of ratio is included.

In the embodiment, the rate of resistance change (ΔMR) and temperature characteristic (TCΔMR) of the first magnetoresistive effect elements 13 and 14 may be made substantially equal to those of the second magnetoresistive effect elements 15 and 16 by, for example, adjusting the thicknesses of the magnetic layers constituting the fixed magnetic layer of each of the magnetoresistive effect elements.

Specifically, the rate of resistance change (ΔMR) and temperature characteristic (TCΔMR) may be adjusted as described below.

Now, the rate of resistance change (ΔMR) and temperature characteristic (TCΔMR) of the first magnetoresistive effect elements 13 and 14 each including the three magnetic layers 49, 51, and 53 which constitute the fixed magnetic layer 42 are adjusted to the rate of resistance change (ΔMR) and temperature characteristic (TCΔMR) of the second magnetoresistive effect elements 15 and 16 each including the two magnetic layers 56 and 58 which constitute the fixed magnetic layer 55.

The above-described laminated film used for the experiment shown in FIG. 6 was used as each of the second magnetoresistive effect elements 15 and 16. In this case, the rate of resistance change (ΔMR) of the second magnetoresistive effect elements 15 and 16 was about 11.0%.

The above-described laminated film used for the experiment shown in FIG. 6 was used as each of the second magnetoresistive effect elements 15 and 16. In this case, the temperature characteristic (TCΔMR) of the rate of resistance change of the second magnetoresistive effect elements 15 and 16 was about −3060 (ppm/° C.).

Next, the film configuration of the first magnetoresistive effect elements 13 and 14 included, in order from below, a substrate/a seed layer 40: NiFeCr/an antiferromagnetic layer: IrMn/a pinned magnetic layer 42: [a first magnetic layer 49: Co70 at % Fe30 at % (X)/a nonmagnetic intermediate layer 50: Ru/a second magnetic layer 51: Co90 at % Fe10 at % (Y)/a nonmagnetic intermediate layer 52: Ru/a third magnetic layer: Co90 at % Fe10 at % (Z)]/a nonmagnetic layer 43: Cu/a free magnetic layer 44: [CoFe/NiFe]/a protective layer: Ta. After the elements were formed, the heat treatment in a magnetic field was carried out.

Here, the thickness (X) of the first magnetic layer 49 and the thickness (Y) of the second magnetic layer 51 were fixed, and the thickness (Z) of the third magnetic layer 53 was changed to determine the rate of resistance change (ΔMR) of the first magnetoresistive effect elements 13 and 14.

In addition, the thickness (X) of the first magnetic layer 49 and the thickness (Z) of the third magnetic layer 53 were fixed, and the thickness (Y) of the second magnetic layer 51 was changed to determine the rate of resistance change (ΔMR) of the first magnetoresistive effect elements 13 and 14. The experimental results are shown in FIG. 7.

FIG. 7 indicates that the rate of resistance change (ΔMR) gradually increases as the thickness (Z) of the third magnetic layer 53 increases. Also, FIG. 7 indicates that the rate of resistance change (ΔMR) substantially equal to the rate of resistance change (ΔMR) of the second magnetoresistive effect elements 15 and 16 may be obtained by changing the thickness (Z) of the third magnetic layer 53.

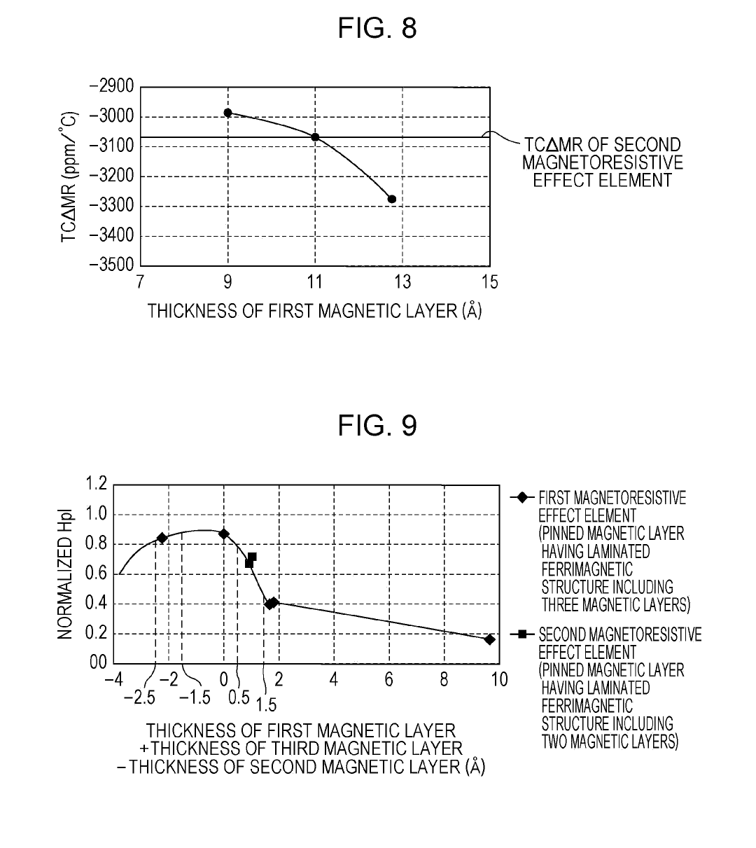

Next, with the first magnetoresistive effect elements 13 and 14 having the above-described film configuration, the thickness (Y) of the second magnetic layer 51 and the thickness (Z) of the third magnetic layer 53 were fixed, and the thickness (X) of the first magnetic layer 49 was changed to measure the temperature characteristic (TCΔMR) of the first magnetoresistive effect elements 13 and 14. The experimental results are shown in FIG. 8.

FIG. 8 indicates that the temperature characteristic (TCΔMR) of the first magnetoresistive effect elements 13 and 14 gradually decreases as the thickness (X) of the first magnetic layer 49 increases. Also, FIG. 8 reveals that the temperature characteristic (TCΔMR) substantially equal to the temperature characteristic (TCΔMR) of the second magnetoresistive effect elements 15 and 16 may be obtained by changing the thickness (X) of the first magnetic layer 49.

Therefore, the rate of resistance change (ΔMR) and the temperature characteristic (TCΔMR) of the first magnetoresistive effect elements 13 and 14 may be simply appropriately adjusted to those of the second magnetoresistive effect elements 15 and 16 by, for example, adjusting the thicknesses of the magnetic layer (the third magnetic layer 53) in contact with the nonmagnetic layer and the magnetic layer (the first magnetic layer 49) in contact with the antiferromagnetic layer 41 among the magnetic layers constituting each of the first magnetoresistive effect elements 13 and 14.

In the embodiment, the number of the magnetic layers constituting the fixed magnetic layer 42 of each of the first magnetoresistive effect elements 13 and 14 is an odd number, and the number of the magnetic layers constituting the fixed magnetic layer 55 of each of the second magnetoresistive effect elements 15 and 16 is an even number. However, as shown in FIGS. 3A and 3B, preferably, the number of the magnetic layers 49, 51, and 53 of each of the first magnetoresistive effect elements 13 and 14 is 3, and the number of the magnetic layers 56 and 58 of each of the second magnetoresistive effect elements 15 and 16 is 2. In this case, the rate of resistance change (ΔMR) and the temperature characteristic (TCΔMR) of the first magnetoresistive effect elements 13 and 14 shown by the experiments in FIGS. 7 and 8 and further the value of element resistance R may be simply appropriately adjusted to those of the second magnetoresistive effect elements 15 and 16. In addition, the heat resistance reliability and the rate of resistance change (ΔMR) of both the first magnetoresistive effect elements 13 and 14 and the second magnetoresistive effect elements 15 and 16, which are described below, may be simply and appropriately improved.

Next, in the embodiment, in the first magnetoresistive effect elements 13 and 14 each including the three magnetic layers 49, 51, and 53 shown in FIG. 3A, an experiment described below was performed for the thickness of each of the magnetic layers 49, 51, and 53 in order to secure the heat resistance reliability against a disturbance magnetic field and to suppress a decrease in the rate of resistance change (ΔMR).

The film configuration of the first magnetoresistive effect elements 13 and 14 including, in order from below, a substrate/a seed layer 40: NiFeCr/an antiferromagnetic layer: IrMn/a pinned magnetic layer 42: [a first magnetic layer 49: Co70 at % Fe30 at % (X)/a nonmagnetic intermediate layer 50: Ru/a second magnetic layer 51: Co90 at % Fe10 at % (Y)/a nonmagnetic intermediate layer 52: Ru/a third magnetic layer: Co90 at % Fe10 at % (Z)]/a nonmagnetic layer 43: Cu (20)/a free magnetic layer 44: [CoFe/NiFe]/a protective layer: Ta. After the elements were formed, the heat treatment in a magnetic field was carried out.

In the experiment, normalized Hpl was determined by changing the value of (the thickness of the first magnetic layer 49+the thickness of the third magnetic layer 53−the thickness of the second magnetic layer 51). Here, “Hpl” represents an external magnetic field intensity with which in the R-H characteristics shown in FIGS. 5 and 6, the rate of resistance change (ΔMR) (here, the rate of resistance change (ΔMR) indicates the ordinate maximum shown in FIGS. 5 and 6) is 2% decreased. The first magnetoresistive effect elements 13 and 14 were maintained for several hours under heating at about 300° C. and a disturbance magnetic field applied perpendicularly to the magnetization direction of the fixed magnetic layer 42. After the elements were returned to room temperature, the Hpl was determined as Hpl1. In addition, Hpl determined at room temperature without heating and applying a perpendicular disturbance magnetic field was regarded as Hpl2. In addition, Hpl1/Hpl2 was determined as normalized Hpl.

FIG. 9 is a graph of the experimental results which shows the relationship between the normalized Hpl and (the thickness of the first magnetic layer 49+the thickness of the third magnetic layer 53−the thickness of the second magnetic layer 51). In this case, the normalized Hpl closer to 1 represents the higher heat resistance reliability against the disturbance magnetic field.

FIG. 9 also shows the normalized Hpl measured for the second magnetoresistive effect elements 15 and 16 each having the laminated film used in the experiment shown in FIG. 6. The second magnetoresistive effect elements 15 and 16 are not provided with the third magnetic layer, and thus (thickness of the first magnetic layer 56−thickness of the second magnetic layer 58) is shown on the abscissa.

FIG. 9 indicates that the normalized Hpl of the second magnetoresistive effect elements 15 and 16 is about 0.7. Therefore, it is preferred that substantially the same normalized Hpl is obtained by the first magnetoresistive effect elements 13 and 14.

FIG. 9 also indicates that when (thickness of the first magnetic layer 49+thickness of the third magnetic layer 53−thickness of the second magnetic layer 51) is larger than about 2 Å, the normalized Hpl tends to be significantly decreased. It is also found that high normalized Hpl is obtained until (thickness of the first magnetic layer 49+thickness of the third magnetic layer 53−thickness of the second magnetic layer 51) becomes about −2.5 Å.

Then, with the first magnetoresistive effect elements 13 and 14 used in the experiment shown in FIG. 9, (the thickness of the first magnetic layer 49+the thickness of the third magnetic layer 53−the thickness of the second magnetic layer 51) was changed by changing the thickness (Z) of the third magnetic layer 53, to determine the rate of resistance change (ΔMR).

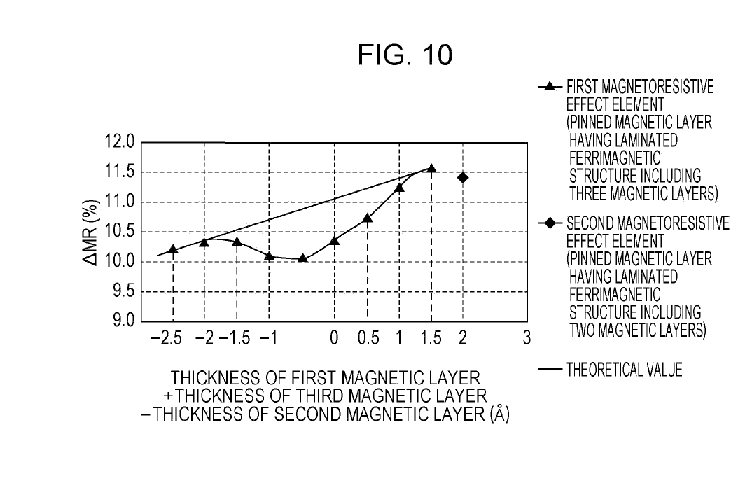

FIG. 10 is a graph of the experimental results which shows the relationship between the rate of resistance change (ΔMR) and (the thickness of the first magnetic layer 49+the thickness of the third magnetic layer 53−the thickness of the second magnetic layer 51). FIG. 10 also shows the rate of resistance change (ΔMR) measured for the second magnetoresistive effect elements 15 and 16 each having the laminated film used in the experiment shown in FIG. 6. The second magnetoresistive effect elements 15 and 16 are not provided with the third magnetic layer, and thus (the thickness of the first magnetic layer 56−the thickness of the second magnetic layer 58) is shown on the abscissa.

FIG. 10 further shows a theoretical line of the relationship between the rate of resistance change (ΔMR) and (the thickness of the first magnetic layer 49+the thickness of the third magnetic layer 53−the thickness of the second magnetic layer 51) of the first magnetoresistive effect elements 13 and 14.

FIG. 10 indicates that the rate of resistance change (ΔMR) deviates from the theoretical value and decreases as (the thickness of the first magnetic layer 49+the thickness of the third magnetic layer 53−the thickness of the second magnetic layer 51) comes close to 0.

The experimental results shown in FIGS. 9 and 10 reveal that when (the thickness of the first magnetic layer 49+the thickness of the third magnetic layer 53−the thickness of the second magnetic layer 51) is made slightly larger or smaller than 0 by adjusting the thickness of the second magnetic layer 51 to be larger than the thicknesses of the first magnetic layer 49 and the third magnetic layer 53, the heat resistance reliability of the first magnetoresistive effect elements 13 and 14 against the disturbance magnetic field may be improved, and a decrease in the rate of resistance change (ΔMR) may be properly suppressed.

Also, it is preferred to exhibit the relationship, the thickness of the second magnetic layer 51>the thickness of the third magnetic layer 53>the thickness of the first magnetic layer 49. As shown in FIG. 7, the rate of resistance change (ΔMR) may be effectively improved by increasing the thickness of the third magnetic layer 53, while the exchange coupling magnetic field (Hex) with the antiferromagnetic layer 41 may be increased by decreasing the thickness of the first magnetic layer 49, so that the magnetization of the fixed magnetic layer 42 may be stably pinned. The experiments shown in FIGS. 9 and 10 indicate that when the thickness of the first magnetic layer 49 is 11 Å, the thickness of the second magnetic layer 51 is 27 Å, and (the thickness of the first magnetic layer 49+the thickness of the third magnetic layer 53−the thickness of the second magnetic layer 51) is about 1 Å in order to achieve high normalized Hpl and a high rate of resistance change (ΔMR), the thickness of the third magnetic layer 53 is about 17 Å, and thus the relationship, the thickness of the second magnetic layer 51>the thickness of the third magnetic layer 53>the thickness of the first magnetic layer 49, is satisfied.

In addition, FIG. 9 indicates that when (the thickness of the first magnetic layer 49+the thickness of the third magnetic layer 53−the thickness of the second magnetic layer 51) is about 0 Å, the normalized Hpl may be desirably significantly increased, while FIG. 10 indicates that in this case, the rate of resistance change (ΔMR) tends to be decreased.

Therefore, it is preferred to avoid adjusting (thickness of the first magnetic layer 49+thickness of the third magnetic layer 53−thickness of the second magnetic layer 51) to 0 Å. Specifically, it is determined that the relationship, 0.5 Å<(the thickness of the first magnetic layer 49+the thickness of the third magnetic layer 53−the thickness of the second magnetic layer 51)<1.5 Å, is preferably satisfied. Consequently, as shown in FIGS. 9 and 10, it is possible to more effectively improve the heat resistance reliability against the disturbance magnetic field and achieve a high rate of resistance change (ΔMR) of the first magnetoresistive effect elements 13 and 14 each including the three magnetic layers 49, 51, and 53 in the pinned magnetic layer 42.

In addition, it is possible to determine that the relationship, −2.5 Å<(the thickness of the first magnetic layer 49+the thickness of the third magnetic layer 53−the thickness of the second magnetic layer 51)<−1.5 Å, is satisfied.

However, it is more preferred that (the thickness of the first magnetic layer 49+the thickness of the third magnetic layer 53−the thickness of the second magnetic layer 51) is adjusted in the range of 0.5 Å to 1.5 Å because the heat resistance reliability against the disturbance magnetic field of the first magnetoresistive effect elements 13 and 14 may be more securely improved, and a high rate of resistance change (ΔMR) may be more securely achieved.

In addition, in the embodiment, the thicknesses of the magnetic layers 49, 51, and 53 constituting the pinned magnetic layer 42 of each of the first magnetoresistive effect elements 13 and 14 are specified as described above. However, with respect to the materials of the magnetic layers, it is preferred that the first magnetic layer 49 is composed of CoxFe100-x (x is in the range of 60 to 100 at %), and the second magnetic layer 51 and the third magnetic layer 53 are composed of CoyFe100-y (y is in the range of 80 to 100 at %).

In addition, in the embodiment, when in the first magnetoresistive effect elements 13 and 14 each including the three magnetic layers 49, 51, and 53 in the pinned magnetic layer 42, the saturation magnetization of each of the magnetic layers is Ms, and the thickness of each of the magnetic layers is t, Ms·t of the second magnetic layer 51 is preferably substantially equal to the total of Ms·t of the first magnetic layer 49 and Ms·t of the third magnetic layer 53. Here, the expression “substantially equal” represents the concept that an error of about ±10% in terms of ratio is included.

Also, in the second magnetoresistive effect elements 15 and 16 each including the two magnetic layers 56 and 58 in the pinned magnetic layer 55, Ms·t of the first magnetic layer 56 is preferably substantially equal to Ms·t of the second magnetic layer 58.

By adjusting Ms·t as described above, the heat resistance reliability of the first magnetoresistive effect elements 13 and 14 against the disturbance magnetic field may be more effectively improved, and a high rate of resistance change (ΔMR) may be more effectively achieved.

In addition, the first magnetoresistive effect elements 13 and 14 each have a laminated structure different from that of the second magnetoresistive effect elements 15 and 16, and thus when both types of the magnetoresistive effect elements are designed to plan-view patterns having the same dimensions, the first magnetoresistive effect elements 13 and 14 show a value of electric resistance R (a value of resistance in a no-magnetic field state where an external magnetic field is not applied) different from that of the second magnetoresistive effect elements 15 and 16. Thus, in the bridge circuit shown in FIG. 4, a midpoint potential may not be precisely obtained. Therefore, in the embodiment, it is preferred that the first magnetoresistive effect elements 13 and 14 have a different plan-view pattern from that of the second magnetoresistive effect elements 15 and 16 so that the value of element resistance R of the first magnetoresistive effect elements 13 and 14 is adjusted to be substantially equal to the value of element resistance R of the second magnetoresistive effect elements 15 and 16. Here, the expression “substantially equal” represents the concept that an error of about ±10% in terms of ratio is included.

The pattern dimensions of the first magnetoresistive effect elements 13 and 14 and the second magnetoresistive effect elements 15 and 16 may be adjusted by, for example, trimming so that the value of element resistance R of the first magnetoresistive effect elements 13 and 14 may be made substantially equal to the value of element resistance R of the second magnetoresistive effect elements 15 and 16.

In FIGS. 1 and 2, the first magnetoresistive effect elements 13 and 14 are disposed on a lower side (the substrate 11 side) in the drawings, and the second magnetoresistive effect elements 15 and 16 are disposed on an upper side, but the positions of the first magnetoresistive effect elements 13 and 14 and the second magnetoresistive effect elements 15 and 16 may be reversed.

In the embodiment, the first magnetoresistive effect elements 13 and 14 and the second magnetoresistive effect elements 15 and 16 may be provided in parallel on the insulating under layer 12 provided on the substrate 11. In this case, the plan-view shape of the magnetic sensor 10 is enlarged, and thus as shown in FIG. 2, the first magnetoresistive effect elements 13 and 14 and the second magnetoresistive effect elements 15 and 16 are preferably laminated with the insulating intermediate layer 17 provided therebetween from the viewpoint of the attempt to miniaturize the magnetic sensor 10.

What is claimed is:

1. A magnetic sensor comprising a plurality of magnetoresistive effect elements which constitute a detection circuit for an external magnetic field,
wherein the magnetoresistive effect elements each have a laminated structure including a pinned magnetic layer having a pinned magnetization direction, a free magnetic layer which is laminated on the pinned magnetic layer with a nonmagnetic layer provided therebetween and which has a magnetization direction varying in response to an external magnetic field, and an antiferromagnetic layer which is formed on the pinned magnetic layer on the side opposite to the nonmagnetic layer and which produces an exchange coupling magnetic field between the antiferromagnetic layer and the pinned magnetic layer by heat treatment in a magnetic field;
the pinned magnetic layer has a laminated ferrimagnetic structure including a plurality of magnetic layers and a nonmagnetic intermediate layer interposed between the respective magnetic layers;
of the plurality of magnetoresistive effect elements, a first magnetoresistive effect element including an odd number of magnetic layers and a second magnetoresistive effect element including an even number of magnetic layers are deposited on the same substrate;
the magnetization direction of the magnetic layer in contact with the nonmagnetic layer among the magnetic layers which constitute the pinned magnetic layer of the first magnetoresistive effect element is antiparallel to the magnetization direction of the magnetic layer in contact with the nonmagnetic layer among the magnetic layers which constitute the pinned magnetic layer of the second magnetoresistive effect element; and
the rate of resistance change (ΔMR) and temperature characteristic (TCΔMR) of the first magnetoresistive effect element are substantially equal to those of the second magnetoresistive effect element.

2. A magnetic sensor comprising a plurality of magnetoresistive effect elements which constitute a detection circuit for an external magnetic field, the magnetic sensor,
wherein the magnetoresistive effect elements each have a laminated structure including a pinned magnetic layer having a pinned magnetization direction, a free magnetic layer which is laminated on the pinned magnetic layer with a nonmagnetic layer provided therebetween and which has a magnetization direction varying in response to an external magnetic field, and an antiferromagnetic layer which is formed on the pinned magnetic layer on the side opposite to the nonmagnetic layer and which produces an exchange coupling magnetic field between the antiferromagnetic layer and the pinned magnetic layer by heat treatment in a magnetic field;
the pinned magnetic layer has a laminated ferrimagnetic structure including a plurality of magnetic layers and a nonmagnetic intermediate layer interposed between the respective magnetic layers;
of the plurality of magnetoresistive effect elements, a first magnetoresistive effect element including an odd number of magnetic layers and a second magnetoresistive effect element including an even number of magnetic layers are deposited on the same substrate;
the magnetization direction of the magnetic layer in contact with the nonmagnetic layer among the magnetic layers which constitute the pinned magnetic layer of the first magnetoresistive effect element is antiparallel to the magnetization direction of the magnetic layer in contact with the nonmagnetic layer among the magnetic layers which constitute the pinned magnetic layer of the second magnetoresistive effect element; and
the plan-view pattern of the first magnetoresistive effect element has different dimensions from those of the second magnetoresistive effect element, and the value of element resistance of the first magnetoresistive effect element is substantially equal to that of the second magnetoresistive effect element.

3. The magnetic sensor according to claim 1, wherein the number of the magnetic layers in the first magnetoresistive effect element is 3, and the number of the magnetic layers in the second magnetoresistive effect element is 2.

4. The magnetic sensor according to claim 3, wherein the pinned magnetic layer constituting the first magnetoresistive effect element includes a first magnetic layer, the nonmagnetic intermediate layer, a second magnetic layer, the nonmagnetic intermediate layer, and a third magnetic layer, which are laminated in order from the side in contact with the antiferromagnetic layer, the third magnetic layer being in contact with the nonmagnetic layer; and
the thickness of the second magnetic layer is larger than the thicknesses of the first magnetic layer and the third magnetic layer.

5. The magnetic sensor according to claim 4, wherein the relationship, the thickness of the second magnetic layer>the thickness of the third magnetic layer>the thickness of the first magnetic layer, is satisfied.

6. The magnetic sensor according to claim 4, wherein the relationship, 0.5 Å<(the thickness of the first magnetic layer+the thickness of the third magnetic layer−the thickness of the second magnetic layer)<1.5 Å, is satisfied.

7. The magnetic sensor according to claim 4, wherein the relationship, −2.5 Å<(the thickness of the first magnetic layer+the thickness of the third magnetic layer−the thickness of the second magnetic layer)<−1.5 Å, is satisfied.

8. The magnetic sensor according to claim 4, wherein the first magnetic layer is composed of CoₓFe₁₀₀₋ₓ (x is in a range of 60 to 100 at %), and the second magnetic layer and the third magnetic layer are composed of Co_{y}Fe_{100-y} (y is in a range of 80 to 100 at %).

9. The magnetic sensor according to claim 3, wherein when the saturation magnetization of each of the magnetic layers is Ms, and the thickness of each of the magnetic layers is t, Ms·t of the second magnetic layer is substantially equal to the total of Ms·t of the first magnetic layer and Ms·t of the third magnetic layer.

10. The magnetic sensor according to claim 1, wherein the plan-view pattern of the first magnetoresistive effect element has different dimensions from those of the second magnetoresistive effect element, and the value of element resistance of the first magnetoresistive effect element is substantially equal to that of the second magnetoresistive effect element.

11. The magnetic sensor according to claim 1, wherein the first magnetoresistive effect element and the second magnetoresistive effect element are laminated with an insulating intermediate layer provided therebetween.
